(19) United States
(12) Patent Application Publication
(10) Pub. No.: US 2002/0017677 A1
(43) Pub. Date: Feb. 14, 2002

(54) Semiconductor device having laminated gate structure and method for manufacturing the semiconductor device

(76) Inventors: Tetsuya Kai, Yokkaichi-shi (JP); Yoshio Kasai, Herndon, VA (US); Hiroaki Tsunoda, Yokkaichi-shi (JP); Hiroyuki Hagiwara, Yokkaichi-shi (JP); Hideyuki Kobayashi, Yokkaichi-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/892,625

(22) Filed: Jun. 28, 2001

(30) Foreign Application Priority Data
Jun. 29, 2000 (JP) 2000-196869

(51) Int. Cl. H01L 29/76

(52) U.S. Cl. 257/314

(57) ABSTRACT

A method of manufacturing a semiconductor device, comprises the following steps. A silicon film is formed on a semiconductor substrate. A first silicon oxide film is formed on the silicon film by CVD. The silicon film and the first silicon oxide film are heated in an oxidizing atmosphere, thereby increasing the density of the first silicon oxide film and forming a thermal oxide film between the silicon film and the first silicon oxide film.

### CROSS-REFERENCE TO RELATED APPLICATIONS

This application is based upon and claims the benefit of priority from the prior Japanese Patent Application No. 2000-196869, filed Jun. 29, 2000, the entire contents of which are incorporated herein by reference.

### BACKGROUND OF THE INVENTION

1. Field of the Invention

The present invention relates to a semiconductor device having a laminated gate structure and a method for manufacturing the semiconductor device, and more particularly to an interpolysilicon insulating film (ONO film) for use in an EEPROM as a kind of nonvolatile memory device.

2. Description of the Related Art

A description will now be given of the prior art, using, as an example, an EEPROM having a floating gate made of polysilicon. It should be noted that if there is no particular definition, the thickness of any oxide film mentioned below indicates an oxide equivalent electrical thickness calculated on the basis of the capacity of the film determined by electrical capacity measurement.

FIGS. 1A-1C are sectional views useful in explaining a process of manufacturing an essential part of a memory cell transistor of a conventional EEPROM.

As seen from FIG. 1A, a tunnel oxide film 102 is formed on a semiconductor substrate 101. A polysilicon film 103 doped with phosphorus (P) and serving as a floating gate is deposited on the tunnel oxide film 102. Further, as seen from FIG. 1B, a silicon oxide film (hereinafter referred to as a “bottom CVD oxide film”) 104 is deposited on the polysilicon film 103 by CVD. A silicon nitride film 105 is deposited on the bottom CVD oxide film 104. A silicon oxide film (hereinafter referred to as a “top CVD oxide film”) 106 is deposited on the silicon nitride film 105 by CVD.

Thereafter, the density of the top CVD oxide film 106 is increased by a heat treatment executed in an oxidizing atmosphere. The bottom CVD oxide film 104, the silicon nitride film 105 and the top CVD oxide film 106 constitute an ONO film, i.e. an interpolysilicon insulating film having a three-layer structure.

Then, as seen from FIG. 1C, a polysilicon film 107 serving as a control gate is deposited on the top CVD oxide film 106. After that, a gate electrode is formed by photolithography and dry etching.

The above-described manufacturing method, however, has problems as described below.

In the above method, after forming the interpolysilicon insulating film, the density of the top CVD oxide film 106 is increased by a heat treatment executed in an oxidizing atmosphere. Since, however, the silicon nitride film 105 below the top CVD oxide film 106 interrupts the passing of an oxidizing agent therethrough, the density of the bottom CVD oxide film 104 below the silicon nitride film 105 cannot be increased.

In this case, compared to the top CVD oxide film 106 having its density increased, the quality of the bottom CVD oxide film 104 is degraded, and hence a larger amount of current leaks through the film 104. If a large amount of current leaks through the bottom CVD oxide film 104, charge accumulated in the floating gate will leak, thereby degrading the reliability of the memory cell transistor, and accordingly reducing the reliability of the EEPROM having such memory cell transistors.

On the other hand, when using a thermal oxide film instead of the bottom CVD oxide film 104, the polysilicon film constituting the floating gate is oxidized into a thermal oxide film. In this case, a quality nonuniform thermal oxide film may be formed as a result of the influence of the quality nonuniformity of the polysilicon film. This causes leakage of a larger amount of current than in the case of forming the bottom oxide film by CVD, thereby degrading the reliability of the EEPROM.

### BRIEF SUMMARY OF THE INVENTION

The present invention has been developed to solve the above problems and aims to provide a highly reliable semiconductor device having a high-quality gate oxide film formed by CVD and a gate oxide film of a small amount of leak current, and also provide a method for manufacturing the semiconductor device.

To satisfy the aim, according to a first aspect of the invention, there is provided a method of manufacturing a semiconductor device, comprising the steps of: forming a silicon film on a semiconductor substrate; forming a first silicon oxide film on the silicon film by CVD; and heating the silicon film and the first silicon oxide film in an oxidizing atmosphere, thereby increasing a density of the first silicon oxide film and forming a thermal oxide film between the silicon film and the first silicon oxide film.

In the above-described semiconductor device manufacturing method, the silicon film and the first silicon oxide film on the silicon film are heated in an oxidizing atmosphere, thereby enhancing the quality of the gate oxide film that is formed of the first silicon oxide film and the thermal oxide film. As a result, the leak current of the gate oxide film is reduced. Thus, the manufacturing method can provide a highly reliable semiconductor device.

To satisfy the aim, according to a second aspect of the invention, there is provided a method of manufacturing a semiconductor device, comprising the steps of: forming a first silicon oxide film on semiconductor substrate; forming a first polysilicon film on the first silicon oxide film; forming a second silicon oxide film on the first polysilicon film by CVD; heating the first polysilicon film and the second silicon oxide film in an oxidizing atmosphere, thereby increasing a density of the second silicon oxide film, and forming a thermal oxide film between the first polysilicon film and the second silicon oxide film; forming a silicon nitride film on the second silicon oxide film; forming a third silicon oxide film on the silicon nitride film by CVD; heating the resultant structure in an oxidizing atmosphere; and forming a second polysilicon film on the third silicon oxide film.

In the above-described semiconductor device manufacturing method, the first polysilicon film and the second silicon oxide film thereon are heated in an oxidizing atmosphere, thereby enhancing the quality of the gate oxide film that is formed of the second silicon oxide film and the thermal oxide film. As a result, the leak current of the gate oxide film is reduced. Thus, the manufacturing method can provide a highly reliable semiconductor device.

To satisfy the aim, according to a third aspect of the invention, there is provided a semiconductor device comprising: a first silicon oxide film formed on a semiconductor substrate; a floating gate electrode formed on the first silicon oxide film; a thermal oxide film formed on the floating gate electrode and having a density of 2.185 g/cm³-2.200 g/cm³; a second silicon oxide film formed on the thermal oxide film; a silicon nitride film formed on the second silicon oxide film; a third silicon oxide film formed on the silicon nitride film; and a control gate electrode formed on the third silicon oxide film.

In the above-described semiconductor device, the thermal oxide film and the second silicon oxide film thereon constitute a high-quality gate oxide film. As a result, the leak current of the gate oxide film is reduced, which enhances the reliability of the semiconductor device.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently embodiments of the invention, and together with the general description given above and the detailed description of the embodiments given below, serve to explain the principles of the invention.

FIGS. 1A-1C are sectional views useful in explaining processes employed in a conventional method for manufacturing a semiconductor device;

FIGS. 2A-2C are sectional views useful in explaining a first process employed in a method for manufacturing a semiconductor device according to the embodiment of the present invention;

FIGS. 3A and 3B are sectional views useful in explaining a second process employed in the method for manufacturing a semiconductor device according to the embodiment of the present invention;

FIG. 4 is a graph illustrating the relationship between the density of a bottom CVD oxide film and the thickness of a thermal oxide film (an increase in the thickness of the thermal oxide film) in the semiconductor device;

FIG. 5 is a graph illustrating the relationship between the thickness of the thermal oxide film (an increase in the thickness of the thermal oxide film) and the density of leak current in the semiconductor device; and

FIG. 6 is a graph illustrating the relationship between the total thickness of the bottom CVD oxide film and the thermal oxide film and the density of leak current in the semiconductor device.

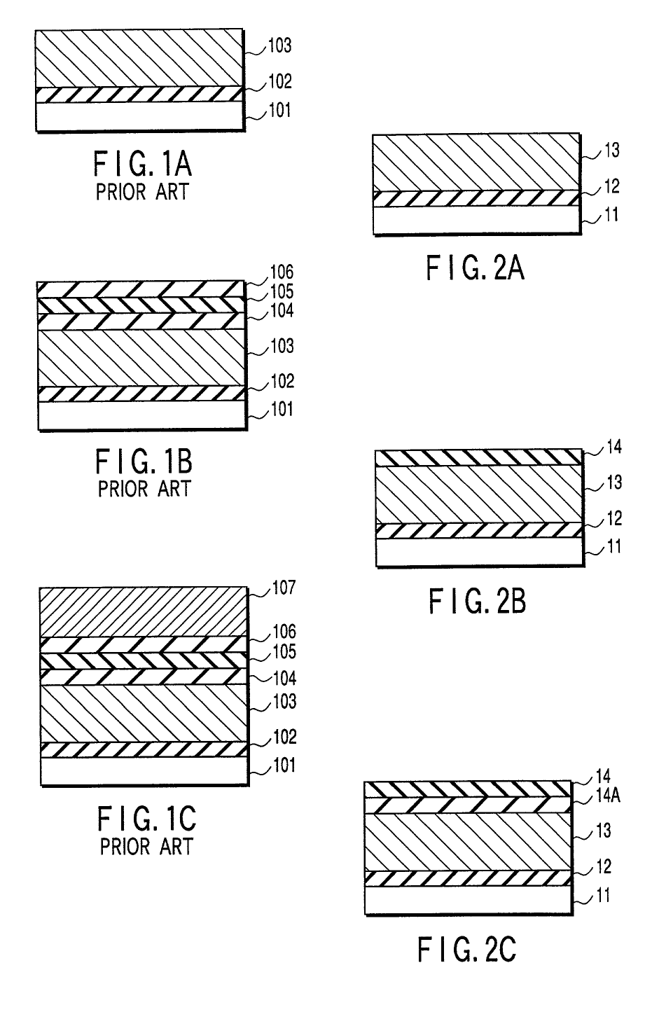

### DETAILED DESCRIPTION OF THE INVENTION

The embodiment of the present invention will be described with reference to the accompanying drawings.

A description will be given of a case where, in an EEPROM having a floating gate, a bottom CVD oxide film on the floating gate is thermally treated in the atmosphere of N₂O as an oxidizing gas. The floating gate is formed of a polysilicon film. An interpolysilicon insulating film formed of an ONO film is provided on the floating gate. The ONO film is obtained by providing, on the floating gate, the bottom CVD oxide film, a silicon nitride film and a top CVD oxide film in this order.

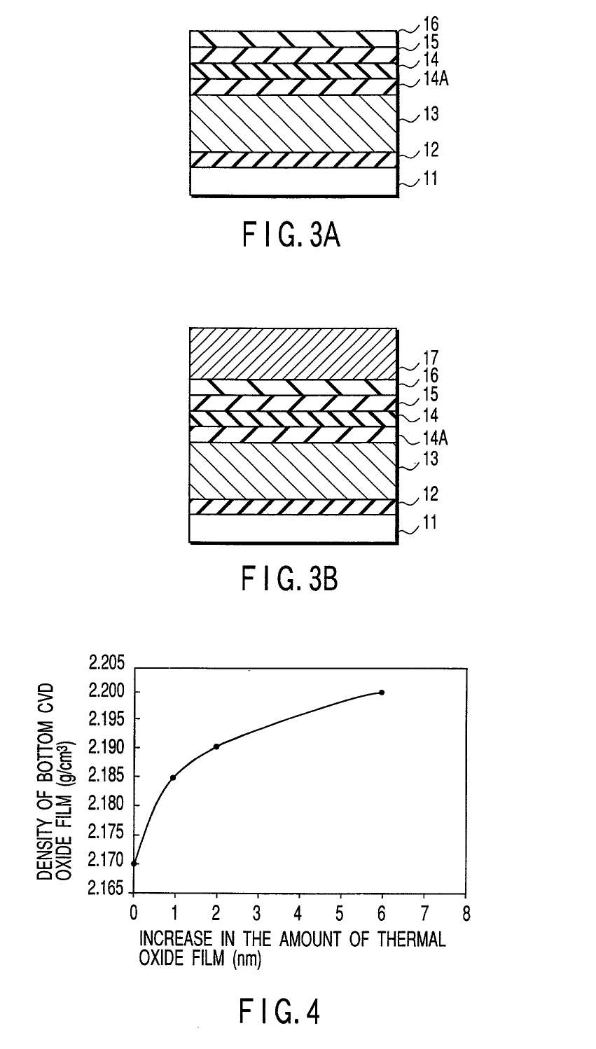

FIGS. 2A-2C, 3A and 3C are sectional views illustrating a process for manufacturing an essential part of a memory cell transistor employed in the EEPROM according to the embodiment of the invention.

As seen from FIG. 2A, a tunnel oxide film 12 consisting of a silicon oxide film is formed on a semiconductor substrate 11 by thermal oxidation. A polysilicon film 13 doped with phosphorus (P) and serving as a floating gate is provided on the tunnel oxide film 12.

Further, as seen from FIG. 2B, a silicon oxide film (hereinafter referred to as a “bottom CVD oxide film”) 14 is deposited on the polysilicon film 13 by CVD.

Subsequently, the structure shown in FIG. 2B is subjected to a heat treatment executed in an oxidizing atmosphere, for example, in the atmosphere of N₂O. As a result, the density of the bottom CVD oxide film 14 is increased. At the same time as the density increasing treatment, the polysilicon film 13 is oxidized, thereby forming a thermal oxide film 14A between the polysilicon film 13 and the bottom CVD oxide film 14 as shown in FIG. 2C. It is preferable to sequentially execute, in the same chamber, the process of forming the bottom CVD oxide film 14 and the process of forming the thermal oxide film 14A by the heat treatment in the oxidizing atmosphere.

After forming the bottom CVD oxide film 14 and heating it, a silicon nitride film (hereinafter referred to as a “CVD silicon nitride film) 15 is deposited by CVD on the bottom CVD film 14 as shown in FIG. 3A. A silicon oxide film (hereinafter referred to as a “top CVD oxide film”) 16 is deposited on the CVD silicon nitride film 15 by CVD.

Subsequently, the structure shown in FIG. 3A is subjected to a heat treatment in an oxidizing atmosphere, for example, in the atmosphere of N₂O. As a result, the density of the top CVD oxide film 16 is increased. The bottom CVD oxide film 14, the CVD silicon nitride film 15 and the top CVD oxide film 16 constitute an ONO film, i.e. an interpolysilicon insulating film having a three-layer structure.

Then, as seen from FIG. 3B, a polysilicon film 17 serving as a control gate is deposited on the top CVD oxide film 16. After that, a gate electrode is formed by photolithography and dry etching.

In the above-described manufacturing method, the bottom CVD oxide film 14 on the polysilicon film 13 serving as the floating gate is subjected to a heat treatment of approx. 900° C. in the atmosphere of N₂O as an oxidizing gas. The pressure of the N₂O atmosphere is set at 10 Torr or less.

If the total thickness of the thermal oxide film 14A and the bottom CVD oxide film 14 formed by the heat treatment (at approx. 900° C. in the atmosphere of N₂O) is 6 nm, the relationship between the density of the bottom CVD oxide film 14 and the thickness (an increase in the thickness) of the thermal oxide film 14A is as shown in FIG. 4.

As is evident from FIG. 4, if the thickness of the thermal oxide film 14A is 0, i.e. if no heat treatment is executed, the density of the bottom CVD oxide film 14 is 2.170 g/cm³. However, if a heat treatment is executed in an oxidizing atmosphere so that the resultant thermal oxide film 14A has a thickness of 1-2 nm, the density of the bottom CVD oxide film 14 is increased to 2.185-2.190 g/cm³. Furthermore, if the resultant thermal oxide film 14A has a thickness of 6 nm, the density of the bottom CVD oxide film 14 is increased to 2.200 g/cm³. It is clear from this that the density of the bottom CVD oxide film 14 is increased by a heat treatment to a value almost equal to the density of the thermal oxide film.

A description will be given of a case where the total thickness of the thermal oxide film 14A and the bottom CVD oxide film 14 formed by the heat treatment is 6 nm, and an electric field of 6 MV/cm is applied to the interpolysilicon insulating film consisting of the thermal oxide film 14A and the bottom CVD oxide film 14.

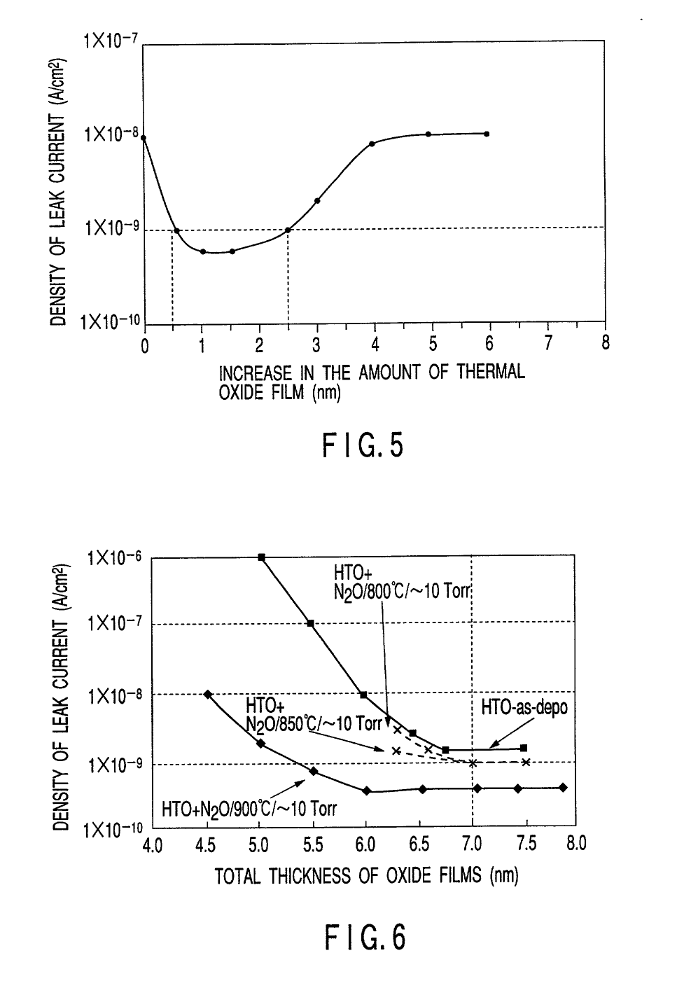

The relationship between the thickness (an increase in the thickness) of the thermal oxide film 14A and the leak current density is as shown in FIG. 5. The pressure of the N₂O atmosphere for the heat treatment is set at 10 Torr or less.

As is understood from FIG. 5, if the thickness of the thermal oxide film 14A is 0, i.e. if no heat treatment is executed, the density of leak current is 1.0×10⁻⁸ A/cm². However, if the thermal oxide film 14A has a thickness of 0.5 nm, the density of leak current is 1.0×10⁻⁹ A/cm², which is approx. one tenth the leak current density obtained in the case where no heat treatment is executed. Furthermore, if a heat treatment is executed so that the resultant thermal oxide film 14A has a thickness of 1-2 nm, the leak current density is reduced to 6.0×10⁻¹⁰ A/cm². This is considered to be the effect of an increase in the density of the bottom CVD oxide film 14.

On the other hand, if the heat treatment is executed so that the thickness of the thermal oxide film 14A is further increased, the leak current density will gradually increase. If the thickness of the thermal oxide film 14A is 2.5 nm or more, the effect of a reduction in the leak current density to one tenth is not attained. Further, if the thickness of the thermal oxide film 14A is 4 nm or more, the leak current density is approx. 1.0×10⁻⁸ A/cm², which is almost equal to that obtained when no heat treatment is executed. Thus, the effect of reducing the leak current density cannot be obtained.

During the heat treatment, the thermal oxide film 14A is created as a result of diffusion of an oxidizing seed into the polysilicon film (floating gate) 13 located below the bottom CVD oxide film 14. If the polysilicon film 13 is nonuniform in quality, the thermal oxide film 14A is influenced by the nonuniformity of the film 13 and becomes a quality nonuniform oxide film. From this, the reason why a reduction in leak current disappears becomes clear. The increase of the quality nonuniform thermal oxide film increases the density of the leak current, if a strong oxidizing heat treatment is executed so that the thermal oxide film more greatly influences the leak current than the CVD oxide film.

A description will now be given of a case where the bottom CVD oxide film 14 provided on the polysilicon film 13 as the floating gate is heated at 800 or 850° C., and 900° C. in the atmosphere of N₂O as an oxidizing gas, and then an electric field of 6 MV/cm is applied to an interpolysilicon insulating film formed of only the thermal oxide film 14A and the bottom CVD oxide film 14.

FIG. 6 illustrates the relationship between the total thickness (total oxide film thickness) of the bottom CVD oxide film 14 and the thermal oxide film 14A, and the density of leak current.

When no heat treatment is executed and the total oxide film thickness is 7 nm or more, the leak current density is a constant value of 2.0×10⁻⁹ A/cm². If, however, the total oxide film thickness is less than 7 nm, the leak current density increases, and if it is less than 6 nm, the leak current density increases more greatly.

On the other hand, when a heat treatment of 900° C. is executed and the total oxide film thickness is 7 nm or more, the leak current is approx. half the value obtained when no heat treatment is executed. When the heat treatment of 900° C. is executed and the total oxide film thickness is less than 7 nm, the leak current is reduced to one tenth or more the above value.

Further, when a heat treatment of 800 or 850° C. is executed, the leak current density is substantially the same as that obtained when no heat treatment is executed. Even if the total oxide film thickness is less than 7 nm, there is almost no leak current reduction effect. This indicates that a treatment temperature of 900° C. or more is necessary in order to increase the density of the bottom CVD oxide film by a heat treatment.

It is understood from the above results that in order to reduce the leak current of the bottom CVD oxide film 14 to one tenth or more by a heat treatment, an oxidizing heat treatment must be executed at 900° C. or more so that the resultant thermal oxide film 14A has a thickness of 0.5-2.5 nm and the total thickness of the resultant bottom CVD oxide film 14 and thermal oxide film 14A is 7 nm or less.

In the prior art, even if a heat treatment is executed in an oxidizing atmosphere after forming the top CVD oxide film 106, the density of the bottom CVD oxide film 104 does not increase. Further, the leak current increases when the floating gate polysilicon film is heated in the oxidizing atmosphere to form a thermal oxide film, instead of the bottom CVD oxide film 104. The above-described embodiment can solve these problems and provide a highly reliable EEPROM.

In the embodiment, where a silicon oxide film is formed by CVD on a semiconductor substrate, a heat treatment must be executed at 900° C. or more in the atmosphere of N₂O or NO gas, so that the resultant thermal oxide film has a thickness of 0.5-2.5 nm and the total thickness of the resultant bottom CVD oxide film and thermal oxide film is 7 nm or less. This can improve the quality of the silicon oxide film formed by CVD, while keeping low the degree of the oxidation of the semiconductor substrate which will cause an increase in leak current. As a result, the leak current flowing through the silicon oxide film can be reduced.

Although in the embodiment, N₂O is used as an oxidizing gas in the heat treatment executed in the oxidizing atmosphere, NO may be used instead. A heat treatment in the atmosphere of NO can provide the same advantage as the above.

Furthermore, although in the above embodiment, a polysilicon film is provided below the bottom CVD oxide film 14, the same advantage can be obtained even if an amorphous silicon film is used in place of the polysilicon film.

In addition, in the embodiment, the polysilicon film below the bottom CVD oxide film 14 is doped with phosphorus (P). However, the same advantage can be obtained even if a polysilicon film doped with an impurity other than phosphorus, such as As (arsenic) or B (boron) is used.

As described above, the present invention can provide a highly reliable semiconductor device having a high-quality gate oxide film formed by CVD and a gate oxide film of a small amount of leak current, and also provide a method for manufacturing the semiconductor device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising the steps of:
forming a silicon film on a semiconductor substrate;
forming a first silicon oxide film on the silicon film by CVD; and
heating the silicon film and the first silicon oxide film in an oxidizing atmosphere, thereby increasing a density of the first silicon oxide film and forming a thermal oxide film between the silicon film and the first silicon oxide film.

2. The method according to claim 1, further comprising the steps, executed after the heating step, of:
forming a silicon nitride film on the first silicon oxide film; and
forming a second silicon oxide film on the silicon nitride film by CVD.

3. The method according to claim 1, wherein the silicon film constitutes a gate electrode, and the first silicon oxide film and the thermal oxide film constitute a gate insulating film.

4. The method according to claim 3, wherein the gate electrode is a floating gate electrode.

5. The method according to claim 1, wherein the silicon film is one of a polysilicon film and an amorphous silicon film.

6. The method according to claim 1, wherein the silicon film is doped with one of P (phosphorous), B (boron) and As (arsenic).

7. The method according to claim 1, wherein the heating step is executed at 900° C. or more, and a total thickness of the first silicon oxide film and the thermal oxide film is 7 nm or less.

8. The method according to claim 1, wherein the step of forming the first silicon oxide film and the heating step are executed sequentially in a chamber.

9. The method according to claim 1, wherein the heating step is executed in an oxidizing atmosphere containing N₂O.

10. The method according to claim 1, wherein the heating step is executed in an oxidizing atmosphere containing NO.

11. A method of manufacturing a semiconductor device, comprising the steps of:
forming a first silicon oxide film on semiconductor substrate;
forming a first polysilicon film on the first silicon oxide film;
forming a second silicon oxide film on the first polysilicon film by CVD;
heating the first polysilicon film and the second silicon oxide film in an oxidizing atmosphere, thereby increasing a density of the second silicon oxide film, and forming a thermal oxide film between the first polysilicon film and the second silicon oxide film;
forming a silicon nitride film on the second silicon oxide film;
forming a third silicon oxide film on the silicon nitride film by CVD;
heating the resultant structure in an oxidizing atmosphere; and
forming a second polysilicon film on the third silicon oxide film.

12. The method according to claim 11, wherein the first polysilicon film constitutes a floating gate electrode, and the second silicon oxide film and the thermal oxide film constitute a gate insulating film.

13. The method according to claim 11, wherein the first polysilicon film is doped with one of P (phosphorous), B (boron) and As (arsenic).

14. The method according to claim 11, wherein the heating step is executed at 900° C. or more, and a total thickness of the second silicon oxide film and the thermal oxide film is 7 nm or less.

15. The method according to claim 11, wherein the heating step is executed in an oxidizing atmosphere containing N₂O.

16. The method according to claim 11, wherein the heating step is executed in an oxidizing atmosphere containing NO.

17. The method according to claim 11, wherein the thermal oxide film has a thickness of 0.5-2.5 nm.

18. A semiconductor device comprising:
a first silicon oxide film formed on a semiconductor substrate;
a floating gate electrode formed on the first silicon oxide film;
a thermal oxide film formed on the floating gate electrode and having a density of 2.185 g/cm³-2.200 g/cm³;
a second silicon oxide film formed on the thermal oxide film;
a silicon nitride film formed on the second silicon oxide film;
a third silicon oxide film formed on the silicon nitride film; and
a control gate electrode formed on the third silicon oxide film.

19. The semiconductor device according to claim 18, wherein the thermal oxide film has a thickness of 0.5-2.5 nm.

20. The semiconductor device according to claim 18, wherein a total thickness of the second silicon oxide film and the thermal oxide film is 7 nm or less.
